(19) United States
(12) Patent Application Publication
(10) Pub. No.: US 2014/0203813 A1
(43) Pub. Date: Jul. 24, 2014

(54) METHOD OF ESTIMATING THE STATE OF CHARGE OF AN ELECTRIC BATTERY

(71) Applicant: Ana-Lucia Driemeyer-Franco, Montigny-Le-Bretonneux (FR)

(72) Inventor: Ana-Lucia Driemeyer-Franco, Montigny-Le-Bretonneux (FR)

(73) Assignee: RENAULT s.a.s., Boulogne-billancourt (FR)

(21) Appl. No.: 14/119,126

(22) PCT Filed: May 16, 2012
(86) PCT No.: PCT/FR2012/051116

§ 371 Date: Feb. 12, 2014

(30) Foreign Application Priority Data
May 20, 2011 (FR) 11 01568

(51) Int. Cl. G01R 31/36

(52) U.S. Cl. CPC G01R 31/3658
USPC 324/434

(57) ABSTRACT

A method of estimating a state of charge of an electric battery including a plurality of electric accumulators as cells. The method includes: a) determining a state of charge of each cell of the battery, b) determining a range of use of the battery equal to a maximum predetermined value of the state of charge of a cell minus deviation between the state of charge of a most charged cell and the state of charge of a least charged cell which are determined in a), c) determining the state of charge of the battery as equal to the ratio between the state of charge of the least charged cell determined in a) and the range of use of the battery determined in b).

### TECHNICAL FIELD TO WHICH THE INVENTION RELATES

The present invention relates to the field of electric batteries comprising a plurality of electric accumulators.

It relates more particularly to a method of estimating the state of charge of such an electric battery.

This invention has a particularly advantageous application for estimating the state of charge of an electric traction battery of a motor vehicle.

### TECHNOLOGICAL BACKGROUND

At present, the state of charge of an electric battery is estimated as a function of measurements relative to the whole of the battery, for example as a function of the voltage measured across the terminals of the battery, of the current passing through the battery and/or of the temperature of the battery.

However, an electric battery generally comprises several electric accumulators called cells which have characteristics that are different from each other, such as for example the variation of their capacity and of their internal resistance.

These differences result, on the one hand, from the construction of the battery itself and, on the other hand, because the cells undergo different temperature variations according to their location inside the battery. The characteristics of the cells which depend on their temperature therefore also undergo different temperature variations.

Consequently, the cells forming one and the same battery frequently have different states of charge. This is referred to as unbalance of the battery cells.

When the cells of the battery have different states of charge, the range of use of the battery is imposed by the most charged cell and by the least charged cell.

In fact, the least charged cell of the battery will reach a state of zero charge, that is to say completely discharged, before the other cells are completely discharged. The battery as a whole will therefore be considered as discharged, whereas some of the cells are not completely discharged. The range of use of the battery is therefore limited by the deviation between the most charged cell and the least charged cell.

In this situation of unbalance, the estimation of the state of charge of the battery based on the measured characteristics of the battery as a whole, which roughly corresponds to an average of the state of charge of the cells, has significant inaccuracy. In particular, this average estimation gives a non-zero state of charge value whereas the battery is useless, one of the cells being completely discharged.

This inaccuracy of the estimation of the state of charge of the battery is particularly detrimental in the case of a traction battery of an electric or hybrid vehicle.

In fact, in these vehicles, the state of charge of the battery information is displayed directly on the dashboard of the vehicle so that the driver knows the autonomy of his vehicle.

As the autonomy of an electric vehicle is less than that of a thermal vehicle, it is important to reassure the driver by providing him with information that is as reliable as possible.

Moreover, the driver must be able to base his decisions whilst driving on reliable state of charge information.

An error in the estimation of the state of charge of the battery can result in causing the driver to make a poor decision and in finding himself in a disagreeable situation, for example he finds himself immobilized because of a lack of energy, or even in a dangerous situation, for example if he lacks power whilst overtaking.

### SUBJECT OF THE INVENTION

In order to overcome the abovementioned disadvantages of the prior art, the present invention proposes a method making it possible to provide an accurate and reliable estimation of the state of charge of a battery.

More particularly, according to the invention, there is proposed a method of estimating the state of charge of an electric battery comprising a plurality of electric accumulators called cells, which comprises the following steps:
a) the state of charge of each cell of the battery is determined,
b) a range of use of the battery equal to a maximum predetermined value of the state of charge of a cell minus the deviation between the state of charge of the most charged cell and the state of charge of the least charged cell which are determined in step a) is determined,
c) the state of charge of the battery is determined as being equal to the ratio between the state of charge of the least charged cell determined in step a) and said range of use of the battery determined in step b).

This method of estimating the state of charge of the battery takes account of the possible unbalance between the cells of the battery.

By means of this method, the estimated value of the state of charge of the battery indicates a maximum charge, that is to say in practice equal to 100%, when the most charged cell has a maximum state of charge, in practice equal to 100%, and indicates a minimum charge, in practice equal to 0%, when the least charged cell has a minimum state of charge, in practice equal to 0%.

Moreover, the method according to the invention makes it possible to obtain a continuous and representative variation of the state of charge of the battery between these two extreme values.

Other non-limiting and advantageous features of the method according to the invention are as follows:
in step a), the following steps are carried out for each cell of the battery:
a1) a value of at least one input variable representative of the functioning of that cell is determined,
a2) a value of at least one output variable representative of the functioning of that cell is determined,
a3) the state of charge of the cell is estimated with the help of a state observer which is based on the value determined in step a1) of said input variable and which is corrected by a correction parameter derived from the value determined in step a2) of said output variable;
said input variable comprises at least the current passing through the cell; said output variable comprises at least the voltage across the terminals of the cell;
each cell is modeled by an electric model circuit comprising in series a voltage generator, a resistor and a component comprising a resistor and a capacitor in parallel;
the values of the resistors and of the capacity of the capacitor of the electric model circuit depend on the temperature of the cell (temp_cell) and/or on the state of charge of the cell and/or on the lifetime of the cell;
said state observer comprises a Kalman filter;

said Kalman filter comprises at least one parameter depending on the functioning of the cell;
said parameter of the Kalman filter depends on the function relating the open circuit voltage of the cell and the state of charge of the cell;
the function relating the open circuit voltage of the cell and the state of charge of the cell is an affine function and said parameter of the Kalman filter is the rate of growth of this function;
the function relating the open circuit voltage of the cell and the state of charge of the cell is a piecewise affine function and a different Kalman filter is used for each range of value of the state of charge of the cell associated with a different affine part of the function relating the open circuit voltage of the cell and the state of charge of the cell;
the Kalman filter used during the implementation of step a) at a given time is determined as a function of the value of the estimated state of charge of the cell at the preceding time;
the transition between a first Kalman filter associated with a first range of value of the state of charge and a second Kalman filter associated with a second range of values of the state of charge is managed by an automated system having hysteresis;
in step a), the state of charge of each cell is determined by an amp-hour-metric metering method; that is to say by means of an amp-hour meter
in step a),
the current entering the battery is integrated,
the state of charge of each cell is determined as a function of the ratio between the integral of the current entering the battery and the capacity of the cell in question; and
the battery in question is a traction battery of a motor vehicle.

### DETAILED DESCRIPTION OF AN EMBODIMENT

The following description referring to the appended drawings, given as non-limiting examples, will give a good understanding of what the invention consists of and of how it can be embodied.

In the appended drawings:

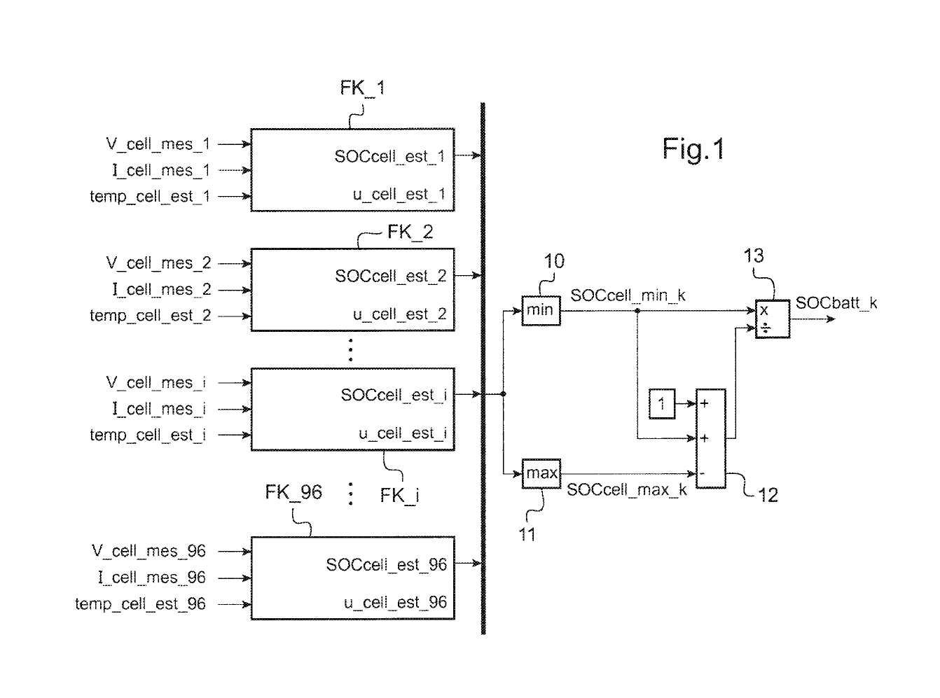

FIG. 1 is a diagrammatic representation of the determination of the state of charge of the battery from the state of charge determined for each cell of the battery,

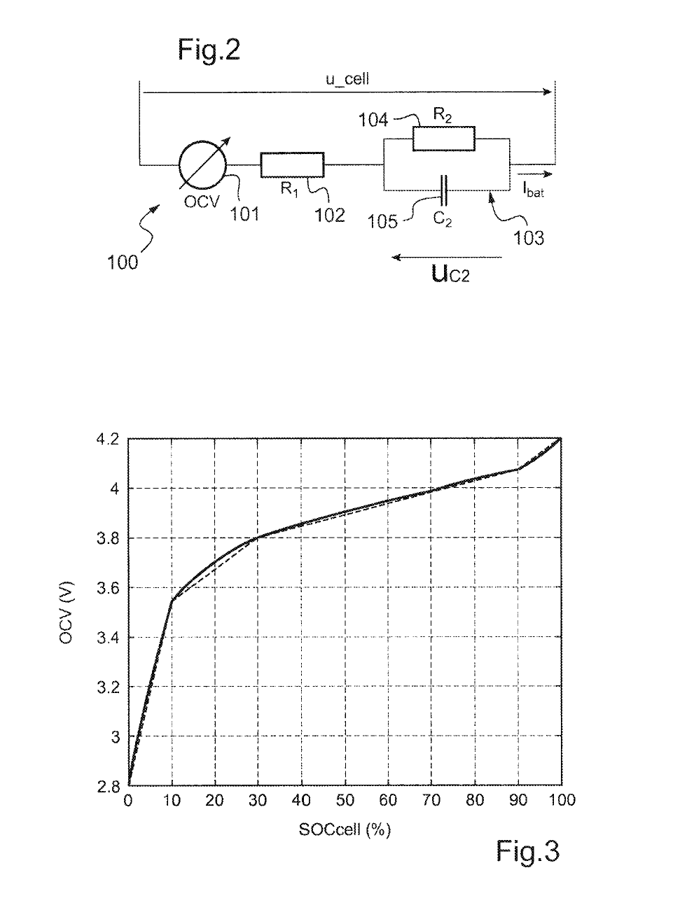

FIG. 2 is a diagrammatic representation of the electric circuit modeling one of the cells of the battery,

FIG. 3 is a diagrammatic representation of the open circuit voltage of a cell as a function of the state of charge of the cell modeled by the circuit shown in FIG. 2 (solid line), and of its approximation as a piecewise affine function (dotted line),

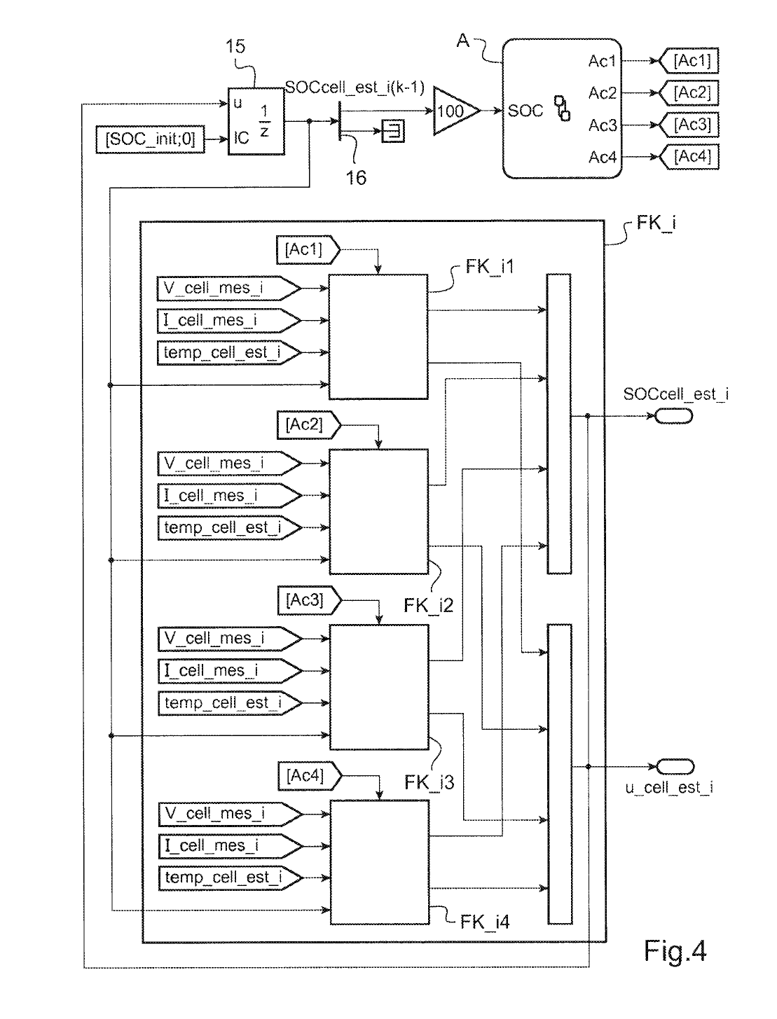

FIG. 4 is a diagrammatic representation of the use of four Kalman filters for estimating the state of charge of the cell modeled by the circuit shown in FIG. 2 each corresponding to a different affine part of the function representing the open circuit voltage of that cell as a function of the state of charge of that cell,

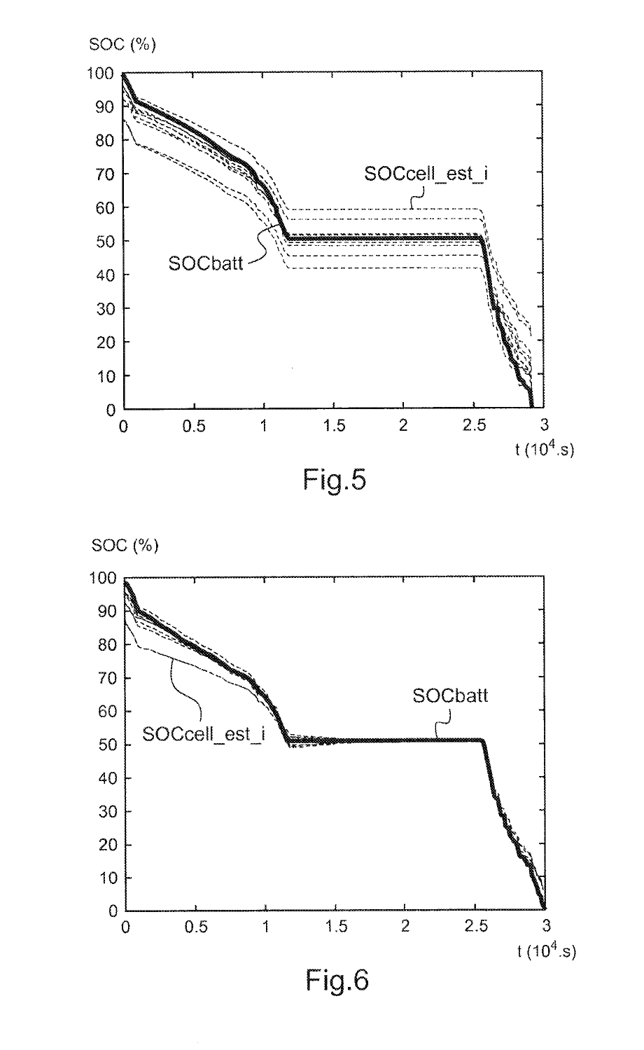

FIG. 5 shows the variation of the state of charge of the battery estimated by the method according to the invention as a function of time (solid line) and the corresponding variation of the state of charge of the cells of the battery (dotted lines), in the absence of a system for balancing the cells,

FIG. 6 shows the variation of the state of charge of the battery estimated by the method according to the invention as a function of time (solid line) and the corresponding variation of the state of charge of the cells of the battery (dotted lines), in the presence of a system for balancing the cells.

Here an electric battery comprising a plurality of electric accumulators connected in series and hereafter called cells is considered.

This electric battery is for example a traction battery of an electric or hybrid motor vehicle. It comprises any number of cells, for example equal to 96.

Hereafter the index i will indicate the magnitudes and the operators associated with the cell of index i, where i takes the values from 1 to 96.

The state of charge of the battery or of a cell is commonly expressed as a percentage of the maximum state of charge of that battery or of that cell.

Hereafter, a state of charge equal to 100% will therefore indicate a battery or a cell that is fully charged, and therefore in a maximum state of charge.

A state of charge of 0% will indicate a battery or a cell that is completely discharged, and therefore in a minimum state of charge.

In practice, the estimation of the state of charge of the battery is carried out at different times, preferably at regular time intervals of period Te, starting from an initial time t0. Hereafter the index k will indicate all of the measurements and calculations carried out at a given time t_k=t0+k·Te. When the time index is omitted, the value of the variable is considered at the time k of the measurement or of the calculation in progress.

The method according to the invention is implemented by an electronic control unit. This electronic control unit is adapted to receive information coming from sensors of the battery adapted to measure different values of voltage, current and temperature inside the battery, as indicated below.

According to the invention, the method of estimating the state of charge, referred to as SOCbatt_k, of the electric battery comprises the following steps:
a) the state of charge referenced SOCcell_est_i of each cell of the battery is determined,
b) a range of use of the battery equal to a maximum predetermined value of the state of charge of a cell minus the deviation between the state of charge referenced SOCcell_max_k of the most charged cell and the state of charge of the least charged cell referenced SOCcell_min_k, that is to say the deviation between the biggest value of state of charge SOCcell_est_i determined in step a) for one of the cells of the battery and the smallest value of state of charge SOCcell_est_i determined in step a) for another of the cells of the battery, is determined,
c) the state of charge of the battery SOCbatt_k is determined as being equal to the ratio between the state of charge of the least charged cell determined in step a) and said range of use of the battery determined in step b).

These three steps are shown in FIG. 1.

The left hand section of FIG. 1 represents the determination of the value of the state of charge SOCcell_est_i of each cell of the battery at the time t_k considered in step a).

Here the value of the state of charge SOCcell_est_i of each cell is estimated by an observer which in this case is a Kalman filter FK_i associated with said cell of index i, at the time t_k.

This being so, the electronic control unit determines, at each time t_k, the state of charge of the most charged cell SOCcell_max_k and the state of charge of the least charged cell SOCcell_min_k at that time, according to the following formulae:

SOCcell_min_{—}k=min(SOCcell_est_{—}i) for i=1 to 96 and SOCcell_max_{—}k=max(SOCcell_est_{—}i) for i=1 to 96.

This step is represented by blocks 10 and 11 in FIG. 1.

In step b), the electronic control unit determines the range of use of the battery at the time t_k, equal to the predetermined maximum value of the state of charge of a cell minus the deviation between the state of charge of the most charged cell SOCcell_max_k and the state of charge of the least charged cell SOCcell_min_k.

The predetermined maximum value of the state of charge of any cell is for example fixed and equal to 100%.

Block 12 in FIG. 1 carries out the calculation of this range of use.

Finally, in step c), the electronic control unit determines the state of charge of the battery SOCbatt_k at the time t_k by calculating the ratio between:
the state of charge SOCcell_min_k of the least charged cell at the time t_k,
and the determined range of use.

This operation is carried out by block 13 of FIG. 1.

In other words, the state of charge SOCbatt of the battery is determined according to the formula:

SOCbatt_{—}k=SOCcell_min_{—}k/(1−(SOCcell_max_{—}k−SOCcell_min_{—}k).

Step a) of determining the state of charge

SOCcell_est_i of each cell of the battery at the time t_k in question can be carried out in different ways.

According to a preferred embodiment of the invention, in step a), the following steps are carried out for each cell of the battery:
a1) a value I_cell_mes_i of at least one input variable i_cell representing the functioning of that cell is determined,
a2) a value V_cell_mes_i of at least one output variable u_cell representing the functioning of that cell is measured,
a3) the state of charge of the cell SOCcell_est_i is estimated with the help of a state observer which is based on the value of said input variable i_cell determined in step a1) and which is corrected by a correction parameter derived from the value of said output variable u_cell measured in step a2).

Moreover, there is preferably also determined a temperature temp_cell_est_i of the cell and the charge of the cell as a function of this temperature is estimated in step a3).

These steps are repeated at each time t_k, for each cell of index i.

More precisely, said input variable comprises at least the current i_cell passing through the cell.

When the battery does not comprise a system for balancing the charges of the cells, this variable is identical to the current I_{bat} passing through the battery itself because, as the cells are connected together in series, the current passing through the battery is equal to the current passing through each cell.

If a system for balancing the charges of the cells is used for making the charges of the different cells uniform at any time, the current i_cell corresponds to the current I_{bat} to which is added the balancing current of the cell because this balancing system is connected in parallel with the cell.

Said output variable comprises at least the voltage u_cell across the terminals of the cell.

These input and output variables are determined for each cell of index i at each time t_k. They are preferably measured.

In the chosen state observer, at least the following are available:
an input variable i_cell whose value is measured at each time t_k in order to update the calculations at each time step,
a state variable SOCcell which is the state of charge of the cell whose estimation SOCcell_est_is sought,
an output variable u_cell whose value is estimated by the observer and compared with a measured value of this output variable, in order to correct the observer in such a way as to make it tend to reality as closely as possible.

In this state observer, the state variable of which it is sought to determine the values is therefore calculated at each time step not only with the help of the measured input variable but also as a function of a correction parameter derived from the output variable.

More precisely, in order to implement this embodiment, each cell is modeled by an electric model circuit 100. An example of such an electric model circuit 100 is shown in FIG. 2.

It comprises, in series, a voltage generator 101 generating a voltage OCV, a resistor 102 of value R1 and a component 103 comprising a resistor 104 of value R2 and a capacitor 105 of capacity C2 in parallel.

R1 corresponds to the internal resistance of the cell, R2 and C2 are used for modeling frequency phenomena inside the cell.

The voltage across the terminals of the component 103 is hereafter referenced Uc2-.

The voltage across the terminals of the closed-circuit model circuit is the voltage u_cell across the terminals of the corresponding cell. The open circuit voltage across the terminals of this model circuit is the voltage OCV which corresponds to the open circuit voltage of the cell.

The current passing through this model circuit is the current passing through the corresponding cell i_cell.

The values R1, R2 of the resistors 102, 104 and the value C2 of the capacity of the capacitor 105 of the electric model circuit 100 preferably depend on the value temp_cell_est_i of the temperature temps_cell of the cell of index i, and/or on the state of charge SOCcell of the cell modeled by the model circuit in question and/or on the lifetime of the cell.

The lifetime of the cell corresponds for example to the time elapsed since its manufacture or to the time elapsed since its putting into service in the electric vehicle. It is a parameter making it possible to quantify the loss of capacity of the cell since the start of its use. In fact, the process of ageing of the cell results in a reduction of the capacity of the cell.

In order to take account of the lifetime of the cell at a time t, it is possible to determine the instantaneous capacity of the cell at that time and to calculate a parameter equal to that instantaneous capacity divided by the initial capacity of the cell at the start of its use.

This parameter is then used for determining the values R1, R2 of the resistors 102, 104 and/or the value C2 of the capacity of the capacitor 105 of the electric model circuit 100.

In practice, these values R1, R2 and C2 constitute parameters of the state observer and are determined by the control unit from pre-established maps as a function of the value temp_cell_est_i of the temperature temp_cell of the cell of index i at the time t_k and as a function of the state of charge of the cell estimated for the time t_k in the preceding calculation step. The value of the temperature temp_cell_est_i can be measured, determined by calculation or estimated from other information on the functioning of the cell.

The state observer FK_i associated with the cell of index i therefore accepts as input the value I_cell_mes_i of the input variable i_cell, the value V_cell_mes_i of the output variable u_cell and the value temp_cell_est_i of the temperature temp_cell of the cell of index i, as shown in FIG. 4.

The state observer comprises for example a Kalman filter.

This Kalman filter comprises at least one parameter depending on the functioning of the cell, for example on the function relating the open circuit voltage OCV of the cell, which corresponds to the voltage generated by the voltage generator 101 in the model circuit 100, and the state of charge SOCcell of the cell.

The open circuit voltage OCV of a cell is a non-linear function of its state of charge SOCcell, and different for each cell chemistry. An example is given in FIG. 3 in solid line.

It is possible to make a piecewise affine approximation of this function, shown in dotted line in FIG. 3.

It is then possible to define a plurality of ranges of values of the state of charge SOCcell of the cell for which this function is an affine function.

Therefore, for each interval of states of charge considered, OCV(SOCcell)=a·SOCcell+b, where a and b are two characteristic parameters of the cell and of the range of states of charge considered.

Hereafter, the total capacity in amp-hours (referenced Ah) of the cell modeled by the model circuit 100 is referenced Qₘₐₓ.

The total capacity is an intrinsic characteristic of each cell and depends on the temperature of the cell and on its lifetime. The cells of a battery have similar, but not necessarily identical, capacities.

The functioning of the model circuit 100 and therefore of the corresponding cell is described by the following equations:

$$\frac{d {U}_{C 2} ( t )}{d t} = - \frac{{U}_{C 2} ( t )}{R 2 \cdot C 2} + \frac{{I}_{bat} ( t )}{C 2}$$

$$\frac{d SOCcell \{ t )}{d t} = \frac{{I}_{bat} ( t )}{{Q}_{max}}$$

$$n\_cell \{ t ) = OCV \{ SOCcell ( t ) ) + R 1 \cdot {I}_{bat} ( t ) + {U}_{C 2} \{ t ) .$$

With a model discretized for example by the Euler method comprising a sampling time equal to the period Te and where each calculation step corresponds to a time t_k and is represented by the index k, the cell is therefore described by the following system of equations:

$$\{ \begin{matrix}{x}_{k - 1} = {A}_{s} {x}_{k} + {B}_{s} {u}_{k} \\ {y}_{k} = {C}_{s} {x}_{k} + {D}_{s} {u}_{k}\end{matrix} \\ where \\ \begin{matrix}{x}_{k} = [ \begin{matrix}{SOCcell}_{k} \\ {U}_{C 2 , k}\end{matrix} ] , & {y}_{k} = {u\_cell}_{k} - b , & {u}_{k} = {I}_{bat , k}\end{matrix} \\ {A}_{s} = [ \begin{matrix}1 & 0 \\ 0 & ( 1 - \frac{Te}{R 2 \cdot C 2} )\end{matrix} ] , \begin{matrix}{B}_{s} = [ \begin{matrix}\frac{Te}{{Q}_{max}} \\ \frac{Te}{C 2}\end{matrix} ] , & {C}_{s} = [ a & 1 ] ,\end{matrix}$$

In this system of equations, Uₖ represents the input variable of the Kalman filter, that is to say in this case the current at the terminals of the cell which is equal to the current at the terminals of the battery to which is possibly added the balancing current of the cell when a balancing system is used, Xₖ represents the state of the system, that is to say in this case the state of charge of the cell and the voltage U_{C2} across the terminals of the component 103 and yₖ represents the output variable. This output variable gives access to an estimated value u_cell_est_i of the voltage across the terminals of the cell of index i at the time k.

The matrices Aₛ, Bₛ and Dₛ are updated at each calculation step, that is to say at each time t_k, since they depend on the parameters R1, R2 and C2, which vary as a function of the value temps_cell_est_i of the temperature temp_cell of the cell and of the state of charge SOCcell of that cell.

As explained previously, the parameters R1, R2 and C2 are given by maps.

During the carrying out of step a) by using the Kalman filter, firstly there is made an estimation of the values of the state and output variables of the Kalman filter. In order to do this, the predicted state at the time t (k+1) is calculated as a function of the state at the time t_k, by means of the characteristic equations of the use of the Kalman filter:

\hat{x}_{k+1∥k}=Aₛ\hat{x}_{k∥k}+Bₛuₖ

ŷ_{k+1∥k}=Cₛ\hat{x}_{k∥k}+Dₛuₖ

Then, the optimum gain Kₖ₊i of the Kalman filter is calculated from the following equations, in which P_{k+1∥k} and P_{k+1∥k+1} are intermediate variables well known to those skilled in the art:

P_{k+1∥k}=AₛP_{k∥k}Aₛ^{T}+Qₖₐₗ

P_{k+1∥k+1}=P_{k+1∥k}−Kₖ₊₁(CₛP_{k+1∥k}Cₛ^{T}+Rₖₐₗ)Kₖ₊₁^{T}

Kₖ₊₁=P_{k+1∥k}Cₛ^{T}(CₛP_{k+1∥k}Cₛ^{T}+Rₖₐₗ)⁻¹

where
Aₛ^{T} and Cₛ^{T} are the transposed matrices of the matrices Aₛ and Cₛ,
Qₖₐᵢ and Rₖₐᵢ respectively correspond to the variance of the state and to the variance of the output. These two parameters constitute adjustment elements of the Kalman filter.

More particularly P_{k+1∥k} is the matrix of predicted estimation of the covariance of the error in the predicted state and P_{k+1∥k+1} is the matrix of a posteriori estimation of the covariance of this error.

Finally, the predicted state \hat{x}_{k+1∥k} is corrected as a function of the error in the estimated output, that is to say as a function of the difference between the measured value of the output variable yₖ₊i and the predicted value ŷ_{i+1∥i} of that output, by carrying out the following calculation:

\hat{x}_{k+1∥k+1}=\hat{x}_{k+1∥k}Kₖ₊₁(yₖ₊₁−ŷ_{k+1∥k}).

The Kalman filter thus gives access to an estimated value SOCcell_est_i of the state of charge SOCcell of the cell of index i and to an estimated value u_cell_est_i of the voltage u_cell across the terminals of the cell of index i.

This estimated value u_cell_est_i of the voltage across the terminals of the cell is equal to ŷ_{i+1∥i}+b (see FIGS. 1 and 4).

As the above equations show, the rate of growth referenced “a” of the affine function relating the open circuit voltage OCV and the state of charge of the cell is a parameter of the Kalman filter used for determining the state of charge of the cell.

A different Kalman filter is therefore used for each range of value of the state of charge of the cell associated with a different affine part of the function relating the open circuit voltage OCV of the cell and the state of charge of the cell.

The Kalman filter used during the implementation of step a) at a given time t_k is therefore determined as a function of the value of the state of charge of the cell estimated at the preceding time t_(k−1).

In the example shown in FIG. 3, the curve representing the open circuit voltage OCV of the cell as a function of its state of charge is approximated by four different affine zones, respectively corresponding to a range of state of charge values between 0 and 10%, 10 and 30%, 30 and 90%, 90 and 100%. A different Kalman filter is therefore used for each of these ranges of state of charge values of the cell in question.

Consequently, in the example described here, for determining the state of charge of the cell shown in FIG. 2, whose curve representing the open circuit voltage OCV of the cell as a function of its state of charge is shown in FIG. 3, four Kalman filters are used, according to the range of state of charge value of the cell.

These different Kalman filters are activated alternately. An example of use of these different filters is shown in FIG. 4, for a cell of index i.

As shown in this figure, the Kalman filter FK_i corresponding to this cell of index i comprises four Kalman filters FK_i1, FK_i2, FK_i3 and FK_i4. Each of these filters is adapted to receive on its input the values of the voltage across the terminals of the cell of index i, of the current passing through this cell and of the temperature of the cell, as well as the values of the state and output variables estimated at the preceding time.

In this respect, block 15 of FIG. 4 accepts at its input the value of the vector Xₖ estimated at the time k and at its output gives the value of the vector Xₖ₊i estimated at the preceding time. As shown in this figure, the vector X₀ of initialization at the time t0 is the vector (SOC_ini, 0), where SOC_ini is the initialization value of the calculation.

The transition between two ranges of values, and therefore between two different Kalman filters, is managed by an automated system A comprising hystereses so as to prevent oscillation between two Kalman filters.

This automated system A accepts on its input the value SOCcell_est_i(k−1) determined at the time preceding the calculation in progress (FIG. 4, block 16 shows that only the value of the first coordinate of the vector is used) for the cell of index i in question. The automated system A transmits, on its output, a signal to activate one of the Kalman filters FK_i1, FK_i2, FK_i3, FK_i4, respectively referenced Ac1x, Ac2, Ac3 or Ac4, according to whether the value of the state of charge at the preceding time SOCcell_est_i(k−1) is included in one or other of the four ranges of values of states of charge defined above.

Only the filter for which the activation signal is transmitted is activated.

In order to avoid oscillation between two Kalman filters corresponding to two adjacent ranges of state of charge values, the transition from one filter to the other is not initiated on the basis of a simple threshold value.

This transition is initiated with hysteresis.

More precisely, the transition between two Kalman filters corresponding to two ranges of state of charge values is initiated when the state of charge of the corresponding cell reaches a threshold value which is different according to the direction of variation of that state of charge at that time.

For example, the move from a first Kalman filter corresponding to a first range of state of charge values to a second Kalman filter corresponding to a second range of state of charge values occurs when the estimated value of the state of charge of the cell reaches a first threshold if the state of charge is increasing.

On the other hand, the return from the second Kalman filter to the first Kalman filter occurs when the estimated value of the state of charge reaches a second threshold, different from the first threshold, if the state of charge is decreasing.

The second threshold is preferably lower than the first threshold.

For example, if state of charge values close to the threshold of 10% between the first and second ranges respectively corresponding to 0-10% and 10-30% are considered, the transition between the filter FK_it corresponding to the first range and the one corresponding to the second range FK_i2 is initiated when the estimated state of charge value increases to reach 10%. On the other hand, the return to the first filter FK_i1 is not initiated when the estimated state of charge value reduces and goes below 10%, but rather when it reduces and reaches 9% for example, that is to say a threshold value lower than 10%.

During such a transition, the Kalman filter is initialized with the previously calculated state of charge value SOCcellest_i(k−1) in order to guarantee a smooth transition and therefore a continuous variation of the estimated state of charge value.

In order to improve the accuracy of the estimation, the parameters Qkal and Rkal of each Kalman filter FK_i, and FK_i1, FK_i2, FK_i3, FK_i4 if several filters are used for a same cell, are adjusted independently for each range of state of charge values.

According to another possible embodiment, in step a), the state of charge of each cell is determined by an amp-hour-metric metering method, that is to say by metering amp-hours.

More precisely, according to this other embodiment,
the current entering the battery is integrated,
the state of charge of each cell is determined from the ratio between the integral of the current entering the battery and the capacity of the cell in question.

In a particularly advantageous manner, the battery in question is a traction battery of an electric or hybrid motor vehicle.

The control unit is then incorporated in the control unit of the vehicle and receives the information transmitted by the various sensors of that vehicle.

Once the state of charge SOCcell of each cell has been obtained, the state of charge is determined according to step c) as described above.

The method according to the invention makes it possible to obtain a battery state of charge value equal to 100% when the state of charge of the most charged cell is 100%, a state of charge value equal to 0% when the state of charge of the least charged cell is 0%, and a continuous and representative variation of the state of charge of the battery between these two extreme values.

This can be seen in FIG. 5 which shows the variation as a function of time of the state of charge of the battery (solid line) estimated according to the method and the state of charge of several cells (dotted lines) for a cycle of discharging the battery.

The variation of the state of charge of the battery follows precisely that of the cells and the initial and final conditions mentioned previously are met.

The method described here can be used for a battery comprising a balancing system the purpose of which is to allow the use of the battery over a maximum range of use in order to increase the autonomy of the vehicle. Such a system is well known to those skilled in the art.

For an initial situation identical to that of the battery in FIG. 5, that is to say an identical initial unbalance of the cells of the battery, in the presence of a balancing system, the estimation of the state of charge of the battery as a function of time is shown in solid line in FIG. 6. The variation, as a function of time, of the corresponding state of charge of the cells is shown in dotted line. The presence of the balancing system makes the estimation of the state of charge of the battery according to the method even more precise, because this estimation is very close to the value of the state of charge of each cell over a large portion of the time of use.

As a variant, during step a) according to the first embodiment, it is possible to increase the order of the Kalman filter used, for example to use a third order filter. It is also possible to consider the use of an adaptive observer which estimates the parameters R1, R2 and C2 at each calculation step instead of using values coming from maps.

If the method is used in the presence of a balancing system, it is possible to take account of the efficiency of the balancing system in order to correct the estimated value of the state of charge of the battery. In this case, the estimated state of charge of the battery will be higher from the start of the balancing.

The method has a particularly advantageous application for estimating the state of charge of the traction battery of an electric or hybrid motor vehicle.

In fact, the state of charge of the battery information is displayed to the driver by the intermediary of a battery gauge on the dashboard.

The driver must be able to base himself on this information in order to make decisions relating to the driving of the vehicle in total safety. It is notably important to provide him with accurate information when the state of charge is low, in order to prevent him from experiencing a loss of energy or a lack of motor power.

In the case where the method is used in the presence of a balancing system, as the state of charge is higher with the balancing, the mileage autonomy of the vehicle displayed to the driver will increase as the balancing takes place.

1-16. (canceled)

17. A method of estimating a state of charge of an electric battery including a plurality of electric accumulators as cells, the method comprising:
a) determining a state of charge of each cell of the battery;
b) determining a range of use of the battery equal to a maximum predetermined value of the state of charge of a cell minus deviation between the state of charge of a most charged cell and the state of charge of a least charged cell which are determined in a);
c) determining the state of charge of the battery as equal to the ratio between the state of charge of the least charged cell determined in a) and the range of use of the battery determined in b).

18. The method as claimed in claim 17, further comprising, in a) for each cell of the battery:
a1) determining a value of at least one input variable representative of functioning of that cell;
a2) determining a value of at least one output variable representative of the functioning of that cell;
a3) estimating the state of charge of the cell with help of a state observer which is based on the value determined in a1) of the input variable and which is corrected by a correction parameter derived from the value determined in a2) of the output variable.

19. The method as claimed in claim 18, wherein the input variable comprises at least a current passing through the cell.

20. The method as claimed in claim 18, wherein the output variable comprises at least a voltage across terminals of the cell.

21. The method as claimed in claim 18, wherein each cell is modeled by an electric model circuit comprising in series a voltage generator, a resistor and a component comprising a resistor and a capacitor in parallel.

22. The method as claimed in claim 21, wherein values of the resistors and of capacity of capacitor of the electric model circuit depend on temperature of the cell and/or on the state of charge of the cell and/or on a lifetime of the cell.

23. The method as claimed in claim 18, wherein the determining the state comprises utilizing a Kalman filter.

24. The method as claimed in claim 23, wherein the Kalman filter comprises at least one parameter depending on functioning of the cell.

25. The method as claimed in claim 24, wherein the at least one parameter of the Kalman filter depends on a function relating an open circuit voltage of the cell and the state of charge of the cell.

26. The method as claimed in claim 25, wherein the function relating the open circuit voltage of the cell and the state of charge of the cell is an affine function and the at least one parameter of the Kalman filter is rate of growth of the function.

27. The method as claimed in claim 25, wherein the function relating the open circuit voltage of the cell and the state of charge of the cell is a piecewise affine function and a different Kalman filter is used for each range of value of the state of charge of the cell associated with a different affine part of the function relating the open circuit voltage of the cell and the state of charge of the cell.

28. The method as claimed in claim 27, wherein the Kalman filter used during a) at a given time is determined as a function of the value of the estimated state of charge of the cell at a preceding time.

29. The method as claimed in claim 27, wherein a transition between a first Kalman filter associated with a first range of value of the state of charge and a second Kalman filter associated with a second range of values of the state of charge is managed by an automated system having hysteresis.

30. The method as claimed in claim 17, wherein, in a), the state of charge of each cell is determined by an amp-hour-metric metering method.

31. The method as claimed in claim 30, wherein, in a),
current entering the battery is integrated,
the state of charge of each cell is determined as a function of the ratio between the integral of the current entering the battery and capacity of the cell in question.

32. The method as claimed in claim 17, wherein the battery is a traction battery of a motor vehicle.
